(19) United States
(12) Patent Application Publication
(10) Pub. No.: US 2004/0080320 A1
(43) Pub. Date: Apr. 29, 2004

(54) Electric shock alert watch

(76) Inventor: Joseph James Golub, Lyme, CT (US)

Correspondence Address: Joseph J. Golub, 51 Norwich Salem Road, Lyme, CT, 06371, US

(21) Appl. No.: 10/277,311

(22) Filed: Oct. 23, 2002

(51) Int. Cl. G01R 29/12

(52) U.S. Cl. 324/457

(57) ABSTRACT

This wrist technology invention uses the latest miniature state of the art electronics to gather, process and display electromagnetic data in order to warn industrial, recreational and environmental health concerned individuals of electric shock, electrocution and biological hazards. It is run by a highly sophisticated custom software controlled microcontroller that is able to quickly measure, process and present data to a user in a form that will allow quick determination of possible surrounding electrical hazards. This technology used is the key in being able to produce this invention in a unique miniature battery operated package the size of a wristwatch. Sophisticated software controlled electronic circuitry relieves the user of complicated setup, calibration, battery/operational checks, processing and operation as this device can literally be run by the push of one button! This device displays its electrical hazard data on a Liquid Crystal Display (LCD) but also has separate audio/visual alarms for special applications. It can be custom tailored to specific market applications by component selection, software reconfiguration and utilizing the appropriate miniature signal pickup.

### BACKGROUND OF INVENTION

1. The Field of Endeavor is

Personal Electrical Shock/Electromagnetic Hazard detection and warning device.

2. References to Specific Problems Involved in Prior State of Technology:

According to the National Institute for Occupational Safety and Health Occupational Injury Deaths 1980-89 report, electrocutions are the fifth leading cause of occupational death accounting for 7% of all occupational deaths! These statistics show that prior state of technology does not appear to adequately warn or protect workers from electrocution hazards. In the U.S. alone, this means over 400 hundred industrial workers die each year inflicting great unnecessary personal losses at a cost to society that is staggering. Aside from large recent plaintiff awards ($6.17 Million electrocution death award in 1997 Pasquale vs. Ohio Power Co.), the National Safety Counsel estimates each workplace death costs $25 million! This figure includes all productivity, medical and administrative expenses. In addition to occupational deaths by electrocution, many public injuries and deaths result from recreational electrical hazards (lightning). Today, studies show that exposure to low frequency electromagnetic fields may present a biological hazard to humans. This Shock Alert watch was invented to fill the need for a convenient, personal non-contact electrical shock or electromagnetic hazard-detection and warning device.

Electrical hazards can be detected by direct contact to the electrical source or by sensing the electromagnetic fields that they produce. Prior state of technology uses direct or very close proximity contact to electrical hazard devices as the primary electrical hazard-warning tool. The potential for electrocution increases just employing these devices and their size makes them even more inconvenient. Research indicates that present devices, which employ proximity pickups, use absolute electromagnetic field measurements. Absolute electromagnetic field devices yield results that are difficult to interpret under certain conditions (i.e. linemen working on street power lines crossing under high power lines) and may require calibration to a standard and periodic recalibration, which is costly and inconvenient. Most electrocution deaths occur upon contact with low frequency time varying Alternating Current (AC) sources. However, Direct Current (DC) electrostatic discharges also can cause death. Prior state of technology does not provide a convenient, personal method of sensing both AC and DC electrical hazards. Prior state of technology relies on large fixed electrostatic discharge (lightning) detection devices (i.e. lightning detectors on large golf courses). This technology does not warn other more mobile outdoor activity participants like fishermen, boaters, and hikers. Prior state of technology electromagnetic field measuring devices are not made in personal, watch size packages providing electrical hazard warning at all times. Prior state of technology does not allow for personal, convenient detection of low frequency electromagnetic fields now suspect in causing biological harm (cancer). By utilizing a miniature, personal device that collects, processes, interprets, and displays electromagnetic hazard information in an easy to use package, industrial and recreational injuries/deaths by electrocution/resultant cancers will be reduced and may be eliminated.

### SUMMARY OF INVENTION

The object of this invention is to allow a wearer to be personally warned of the presence of nearby AC/DC electric shock and biological hazards without direct contact with the electric hazard sources. It works by sensing the presence of the surrounding electromagnetic fields emitted by the electrical hazards. This invention can be tailored for industrial, recreational, and biological hazard detection applications through component (bias setpoint/gain range) selection, customization of software, and utilizing a suitable miniature signal pickup (tri-axial electric field, vertically polarized electric field, wrist/case loop, or ferromagnetic coil). Its operation is analogous to a geiger counter except that it measures low frequency AC and DC electric fields that are produced by the electrical hazard source. In addition to the device's Liquid Crystal Display (LCD) providing electrical hazard status information, separate audio and visual alarm capabilities on the device can be set to alert the operator of any electrical hazard changes. Its displays and alarms can also indicate relative changes from the present source field reading. The miniature microprocessor controlled device automatically performs a self calibration on its internal circuitry upon power up, checks the condition of its battery, takes a present field reading as a relative reference (if so configured), periodically checks itself for proper operation, and warns the user if it is not operating properly. It then monitors the AC and DC electric fields of the surrounding area using a suitable pickup which feeds a ultra high impedance input signal amplifier. The amplifier is controlled by the microprocessor which adjusts its gain to the present field strength and the resultant signal is processed by the microprocessor and the information is displayed to the user. Since this information can be relative to the present “safe” electric surrounding (if configured in relative mode), any electric field changes can alert the user of newly introduced electric/shock hazards. This feature is very important for industrial users as they frequently work in high background electromagnetic fields. The user can readjust as required to any new surrounding reading if they move or if offscale readings are observed by the touch of a button on the device. The device can also operate in a recreational (lightning hazard) or residential (biological hazard) mode in which electrostatic DC/low frequency AC readings are displayed and observed for electric hazard field trends without the need for it to obtain a present reference field reading. Through component selection, software reconfiguration, and pickup selection one can tailor each industrial, recreational and residential electric hazard application by selecting various calibration, battery test, operational check, and audio/visual alarm features. For added convenience, the device also keeps and displays time to the user. The user operates the device by push buttons similar to any modern electronic watch.

Its size and its package offers great advantages for industrial, recreactional, and residential users as potential electrical shock/biological hazards can be checked easily and quickly without need for any additional special test equipment or knowledge. Simultaneous AC and DC electric field displays alert users of alternating (AC) and electrostatic (DC) electrical hazards. An ultra high input sensitivity amplifier is automatically adjusted to measure the hazard produced electromagnetic fields within a large dynamic range to insure reliable operation for linemen, electrical contractors, construction workers, fire & rescue workers, golfers, boaters, fishermen, hikers, biological hazard concerned individuals, and other users.

### BRIEF DESCRIPTION OF DRAWINGS

FIG. 1 is a block diagram of the major components of the invention.

FIGS. 2 and 3 are sample electronic component layouts of the device done to scale to insure the claim that all the required components can fit into a watch-size package.

FIG. 4 is an Electric Shock Alert watch layout.

### DETAILED DESCRIPTION

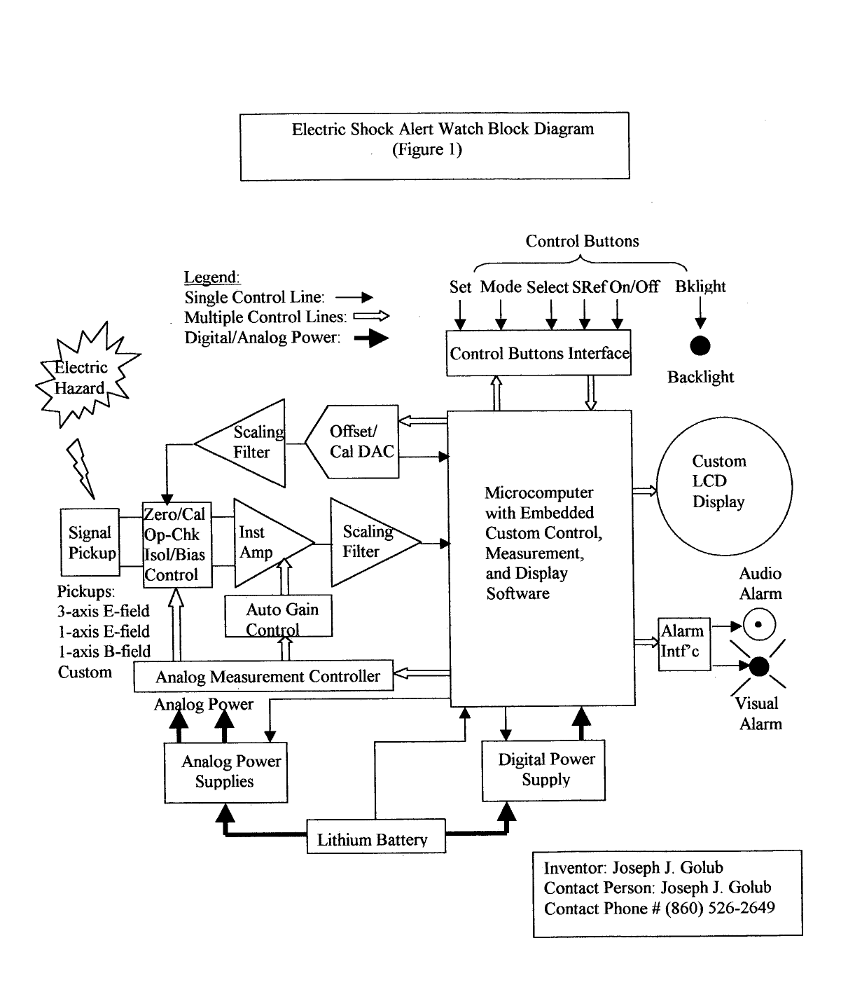

All electronic components in this design were carefully selected for their ultra low power consumption and for their availability in a miniature size to be suitable for this invention. A larger prototype unit was built and tested to confirm that all its claimed operations work properly. The device consists of 4 major blocks: An analog measurement section; An analog control section; A digital processing section and an alarm and display section. These major blocks along with other support sections are shown in FIG. 1. Custom software was written to control all aspects of device operation and resides within the microcontroller of the digital processing section.

The analog measurement section consists of an analog input amplifier with selectable gain and an input sensitivity of 3×10⁻¹⁵ amperes. The amplifier's normal controllable dynamic range is 1000, but can be configured for gains up to 10,000. Bias setting resistors, which establish the input level setpoint, can be matched with the input pickup to suit specific applications. Low frequency AC and DC electric/magnetic fields are collected by a miniature tri-axial, single axis, loop, or ferromagnetic pickup antenna and presented to the input amplifier. In relative mode, the amplifier imposes a gain on the signal depending on the sampled field level of the surrounding area. If the device senses that sufficient signal exists to provide a good onscale present relative (reference) reading, it will lock on to that gain. If not, it automatically adjusts its gain so that sufficient signal exists for an onscale reference reading. If it senses that the signal is outside its dynamic range, it will notify the user. In the recreational and residential modes, absolute electric/magnetic fields are displayed for trends indicating hazard areas that need to be avoided.

The analog measurement section is controlled by the analog control section which consists of a digital to analog converter, electronic analog switches and several operational amplifiers for signal scaling and prefiltering. The analog control section adjusts the gain settings of the input amplifier and performs system self auto-calibration upon startup and operational checks during device use. Power supply voltages and test signals for each analog signal range are injected into the front end of the input amplifier and measured after it is isolated from the signal measurement pickup antenna by electronic analog switches. The test signals are fixed value onscale signals that are generated by the digital to analog converter. If any test signal fails to meet the set pass/fail tolerances, it shuts down the electric hazard sensing portion of the device and notifies the user of the calibration status. In addition, a test signal is injected into the input amplifier periodically during operation (depending on the mode). This feature insures the user that the device is still operating properly during normal operation. If this test signal fails to meet established pass/fail criteria, it also notifies the user of same and shuts itself down. When operating in the residential mode, an electronic analog switch isolates the low impedance pickup coil from the input amplifier to allow a calibration and op-check to occur.

After the signal output of the input sensing amplifier is scaled and filtered correctly by operational amplifiers, it is presented to the analog to digital converter for processing within the microcontroller. The digital processing section consists of a miniature, state-of the-art ultra low power 16-Bit microcontroller with an 84 segment LCD display and a built in 12+2 bit analog-to-digital converter. Proprietary control algorithms were developed and coded in software to perform its unique processing, control and display operations. The microcontroller also keeps and displays time to the user. The microprocessor manipulates the data and presents it to the user in an easy to intrepret format scale of 0-99 (relative to the reference reading-if configured) for both AC and DC hazards. It indicates offscale readings to the user by displaying non-number (OH, OL, etc.) characters representating present reading status. In its recreational and residential modes, it processes data without a reference reading to detect and locate electrostatic/magnetic hazards for those concerned.

The alarm section consists of driver circuitry for Light Emitting Diodes (LED's), pizeoelectric alarms and/or other types of alarms. The rate of visual alarm flashing and audio sound beeping is proportional to the measured electric/magnetic field from the hazard source relative to the field taken as a reference (if configured). A slow constant rate of alarm flashing/beeping indicates to the user that the device is operating properly and the fields have not increased from the chosen reference field. A rapid flashing/beeping (up to 25 hz) indicates a large increase in field change from the reference reading. Again, this is similar to a geiger counter. This is very useful to industrial users as they do not have to constantly monitor the display to be notified of possible hazardous electric shock conditions. If the surrounding field is less than the reference field taken, the device just signals the user at the relative (slow) field rate. Since these separate audio/visual alarms are optional, they can be set for both off, both on or either one on/off as required by the user preference. If both AC and DC readings are desired, the alarms will indicate movement of the larger of the two from its reference. The device is also designed to warn the operator (flashing LCD digit) that a low battery condition exists and shut off the alarms and the sensing portion of the device if a battery reaches a minimum level or the device fails its periodic operational checks as previously noted. Operator buttons and a LCD readout display will allow the operator to set the device's alarms, monitor battery status, display the AC and DC fields, set operational modes and set/display time. A LCD backlight may be added depending on the manufacturers desires. Six operator buttons control all user setting and running of the device, including the backlight. They are named: Set, Mode, Select, Sref (Set reference), E/M On/Off and Backlight. For most users, the pressing of the E/M on/off button will be all that is needed to begin operation.

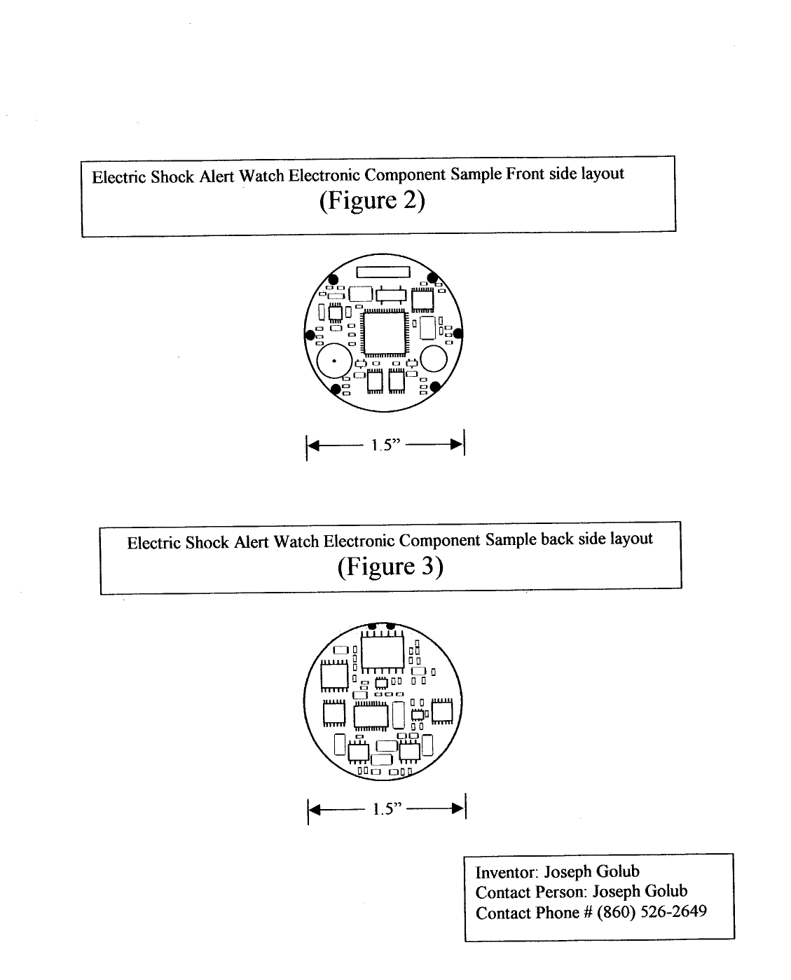

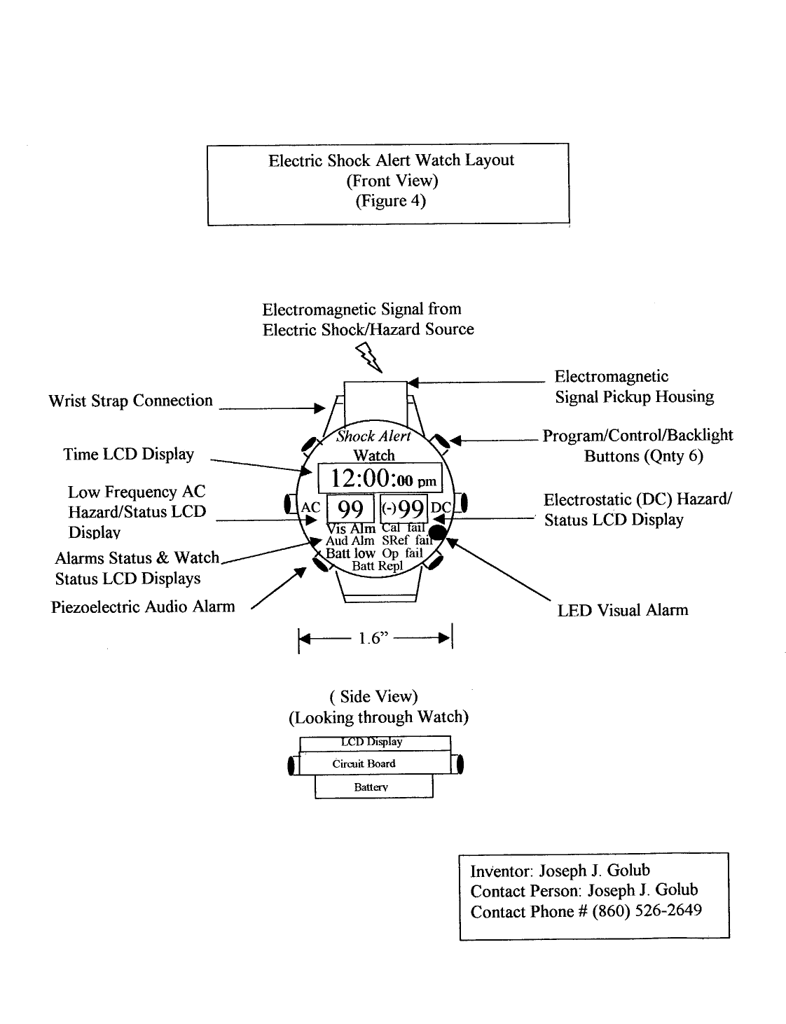

This device is to be manufactured by mounting all electronic components on a double sided multi-layer electronic circuit board (see FIGS. 2 and 3 for component layouts). A custom glass LCD display with segments designed to display time, alarms, status and electric hazard field measurements would be connected to the board. The appropriate sensing pickup antenna can be placed at the top of the device or, depending upon the application, can be around the case or wrist at the manufacturers discretion. A high capacity lithium battery will power the device. All these components would be stacked (display on top, circuit board in middle, battery on bottom) in a watch like case to be worn on a users wrist (see FIG. 4). The manufacturer can add aesthetic and environmental qualities (wristband type, case color, waterproofing, etc.) to the watch package as it deems necessary.

As some specific examples of the device's applications: A utility lineman can be instantly notified if the power lines he is working on inadvertently become energized or become electrically charged by atomspheric conditions and faulty grounds; Rescue workers can be assured that downed power lines that they are approaching at an accident scene are not energized; Firemen entering a building that were told that it has been electrically disconnected are assured that it has! Hi-rise electricians can easily confirm that power is off before starting to work. Recreational users (boaters, golfers, fishermen, hikers, etc.) may take appropriate action when they note increasing electrostatic DC field readings which indicate an increase risk of a possible nearby lightning strike. Lastly, health concerned individuals, prospective/existing tenants, homebuyers and building officials can be notified of higher AC low frequency magnetic field areas for biological hazard avoidance.

This device is different from “old ways” in that it utilizes state-of the-art high technology components that can perform the necessary sophisicated functions in a small enough package as to become unobtrusive and part of a users everyday dress-just like a watch has become. No special knowledge or extra test equipment is required to be setup and operated-it's all contained on the users wrist operated by buttons! By making a warning device so convenient and easy to use, it will be used more! The more it is used, the more it will reduce or help eliminate industrial and recreational injury and/or death by electric shock or electromagnetic hazard exposure. This device is different as it completely checks (calibrates) itself upon startup and periodically during operation. This feature is usually found only in special test equipment. This device is also different as it can measure relative or absolute fields. This means users (especially industrial workers) can be working in a relatively high electromagnetic (shock hazard) surrounding and still be notified of changes in the electric environment-and to newly introduced shock hazards. As for recreational/residential users, it fills a need where “old ways” are too big, cumbersome, and complex to use making them impractical for these applications. For many mobile users, the functionality provided by this device simply doesn't exist. This device also has the ability to read DC electrostatic fields. Static electricity shock and lightning hazards can be detected in recreational mode irregardless of hazard polarity, as the device can read both +/− DC field polarities. In the residential mode, biological hazard sources can be identified without the need of any other special equipment or knowledge of test equipment.

1.) I claim that: This whole invention can be packaged in the size of a wrist watch intended to be used as a personal wrist-worn electrical shock/electromagnetic hazard detection and warning device.

2.) I claim that: This device will simultaneously measure low frequency Alternating Current (AC) Electromagnetic Fields and +/− Direct Current (DC) Electric fields without direct contact of the field source for the purpose of user electric shock and biological hazard avoidance.

3.) I claim that: This invention's microcomputer based miniature, ultra low power design, analog/digital operations and control/processing software are unique.

4.) I claim that: This invention can personally warn industrial users (linemen, construction, electrical contractors, fire, police and rescue workers) of nearby electrocution hazards from commercial power sources (AC) and electrostatic discharge (DC) sources.

5.) I claim that: This invention can warn health concerned individuals (homeowners, renters, building officials) of the presence of low frequency magnetic fields that are suspect in causing biological harm (cancer) in humans.

6.) I claim that: This invention can warn recreational users (golfers, boaters, fishermen, hikers etc.) of the presence of DC electrostatic fields which can indicate that the potential for a nearby lightning strike has increased.

7.) I claim that: This invention can measure low frequency AC and electrostatic DC electric fields relative to a work area background reference set by the user.

8.) I claim that: This invention automatically calibrates itself by the microcomputer injecting test signals into the input amplifier stage to simulate actual electromagnetic field signals.

9.) I claim that: This invention periodically checks itself for satisfactory operation during use.

10.) I claim that: This invention can measure and display the polarity of Direct Current (DC) electrostatic fields present along the sensitive axis of the recreational (DC) signal pickup.

11.) I claim that: This invention can automatically zero itself and adjust its input gain over a dynamic range of 1000 or more to obtain on-scale readings.

12.) I claim that: This invention provides the user with simultaneously updated separate audio and visual alarms so that the user does not need to constantly monitor the LCD display for notification of hazardous conditions.

13.) I claim that: This invention can simultaneously display conventional time along with warning displays/alarms of nearby electric hazards.

14.) I claim that: This invention can be powered by no more than a single Lithium coin type battery.

15.) I claim that: This invention visually warns user of low battery conditions and, if the battery voltage drops to a predetermined level, will shut itself off.

16.) I claim that: This invention visually notifies the user and shut itself off when the calibration fails, or its operational check fails, or the reference reading cannot be taken.
